(19) United States
(12) Patent Application Publication
(10) Pub. No.: US 2022/0037575 A1
(43) Pub. Date: Feb. 3, 2022

(54) THERMOELECTRIC APPARATUS

(71) Applicant: Sumitomo Chemical Co., Ltd., Tokyo (JP)

(72) Inventors: Miguel Angel Carrasco-Orozco, Godmanchester (GB); Simon King, Godmanchester (GB)

(73) Assignee: Sumitomo Chemical Co., Ltd., Tokyo (JP)

(21) Appl. No.: 17/290,333

(22) PCT Filed: Oct. 30, 2019
(86) PCT No.: PCT/GB2019/053072

§ 371 Date: Apr. 30, 2021

(30) Foreign Application Priority Data
Nov. 2, 2018 (GB) 1817981.2

(51) Int. Cl. H01L 35/32; H01L 35/02

(52) U.S. Cl. CPC H01L 35/32; H01L 35/02

(57) ABSTRACT

Thermoelectric apparatus comprising a thermoelectric generator (101), a thermally conductive heat spreader (105) and a thermally conductive heat transfer element (103). In use, the TEG is disposed on a surface of a heated object (10), e.g. a boiler, pipe or electrical equipment. Heat is drawn away from the cold side of the TEG by the thermally conductive heat transfer element. Thermal insulation (107, 109) may be provided between the TEG and the thermally conductive heat spreader and/or over the heat spreader. The apparatus may be provided in kit form for assembly on a surface which is heated when in use.

### BACKGROUND

Embodiments of the present disclosure relate to thermoelectric apparatus and a method and a kit for forming the same.

A thermoelectric generator (TEG) can be used to generate electrical power. A TEG includes at least one thermoelectric couple. A thermoelectric couple includes an n-type thermoelectric leg electrically coupled by a contact to a p-type thermoelectric leg. The TEG may comprise a plurality of electrically connected thermoelectric couples, forming a plurality of alternating n-type thermoelectric legs and p-type thermoelectric legs electrically connected across each leg in series.

In use, a temperature difference may be applied across a contact-thermoelectric element boundary of the TEG. In response to the temperature difference, a voltage is generated by the thermoelectric elements. This voltage can be used to drive a current through the thermoelectric generator.

Power output of the TEG is affected by the temperature differential (DT) between a hot side and a cold side of the TEG.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

A TEG may be provided on apparatus having a surface which is heated when in use, such as electrical equipment, boilers or hot water pipes in settings such as domestic, office and industrial settings. The TEG may power a sensor, such as a temperature sensor. However, the present inventors have found that power output of such a TEG may be limited due to a small DT, particularly if the apparatus is thermally insulated.

The present inventors have found that use of a thermally conductive heat transfer element to draw heat away from the cold side of a TEG and a thermally conductive heat spreader to spread heat conducted away from the cold side by the heat transfer element can significantly increase DT of a TEG resulting in significantly higher power output compared to a TEG which is not provided with a heat transfer element and a heat spreader, particularly in environments where the thermoelectric generator is covered by thermal insulation.

Embodiments of the present disclosure provide thermoelectric apparatus including a thermoelectric generator, a thermally conductive heat spreader and a thermally conductive heat transfer element.

A first surface of the TEG may be configured to contact a heated surface. An opposing second surface of the TEG may be in thermal contact with a proximal end of the thermally conductive heat transfer element.

A distal end of the thermally conductive heat transfer element may be in thermal contact with the thermally conductive heat spreader.

The thermally conductive heat spreader is spaced apart from the thermoelectric generator. The thermally conductive heat spreader may have a surface area larger than a surface area of the distal end of the thermally conductive heat transfer element.

In some embodiments, the thermally conductive heat spreader has a surface area larger than a surface area of the thermoelectric generator.

In some embodiments, the thermally conductive heat transfer element has a single thermally conductive fin extending between the thermoelectric generator and the thermally conductive heat spreader.

In some embodiments, the thermally conductive heat spreader contains or consists of a metal.

In some embodiments, the thermally conductive heat spreader contains or consists of a flexible metal foil.

In some embodiments, a thermal insulator is disposed between the thermoelectric generator and the thermally conductive heat spreader.

In some embodiments, the thermally conductive heat transfer element is incorporated into the first thermal insulator.

In some embodiments, the TEG is laminated to or incorporated into the first thermal insulator.

In some embodiments, the thermally conductive heat spreader is laminated to a surface of the first thermal insulator.

In some embodiments, a second thermal insulator is disposed over, and optionally laminated to, the thermally conductive heat spreader.

Embodiments of the present disclosure provide a sensor system including the thermoelectric apparatus described herein and a sensor powered by the thermoelectric generator.

In some embodiments, the sensor is a temperature sensor.

Embodiments of the present disclosure provide a method of forming the thermoelectric apparatus described herein, the method including: applying the thermoelectric generator to a surface of an object wherein the temperature of the surface increases when the object is in use; disposing the thermally conductive heat transfer element over the second surface of the thermoelectric generator; and disposing the thermally conductive heat spreader over the thermally conductive heat transfer element and spaced apart from the thermoelectric generator.

In some embodiments of the method, a thermal insulator is disposed between the thermoelectric generator and the thermally conductive heat spreader.

Embodiments of the present disclosure provide a kit for assembly of a thermoelectric apparatus, the kit including:

a thermoelectric generator having first surface configured to contact a heated surface and an opposing second surface;

a thermally conductive heat transfer element having a proximal end configured to contact the second surface of the thermoelectric generator and to draw heat from the second surface of the thermoelectric generator to the distal end; and

a thermally conductive heat spreader configured to contact the distal end of the thermally conductive heat transfer element, the thermally conductive heat spreader having a surface area larger than a surface area of the distal end of the thermally conductive heat transfer element.

In some embodiments, the kit further includes a thermally conductive adhesive for adhering the proximal end of the thermally conductive heat transfer element to the second surface of the thermoelectric generator and/or for adhering the distal end of the thermally conductive heat transfer element to the thermally conductive heat spreader.

In some embodiments, the kit further comprises a first thermal insulator.

In some embodiments the thermally conductive heat transfer element is incorporated into the first thermal insulator; and/or the TEG is laminated to or incorporated into the first thermal insulator; and/or the thermally conductive heat spreader is laminated to the first thermal insulator.

In some embodiments, the kit further comprises a second thermal insulator having at least the same surface area as the thermally conductive heat spreader. In some embodiments, the thermally conductive heat spreader is laminated to a surface of the second thermal insulator.

It will be understood that the kit may contain, without limitation, no thermal insulator; only one of the first and second thermal insulators; or both of the first and second thermal insulators.

In some embodiments, the kit further includes a thermal insulator. The thermal insulator may have at least the same surface area as the heat spreader.

In some embodiments, the kit further includes instructions for assembly of the thermoelectric apparatus.

### BRIEF DESCRIPTION OF DRAWINGS

The present disclosure is described in conjunction with the appended figures. It is emphasized that, in accordance with the standard practice in the industry, various features are not drawn to scale. In fact, the dimensions of the various features may be arbitrarily increased or reduced for clarity of discussion.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 is a schematic cut-away view of thermoelectric apparatus according to some embodiments;

FIG. 2 is a schematic cross-section of a TEG according to some embodiments for use in thermoelectric apparatus as described herein;

FIG. 3 is a schematic illustration of a thermoelectric system according to some embodiments;

FIG. 4 is a graph of DT across a TEG vs distance across a TEG perpendicular to the heat transfer element for modelled thermoelectric apparatus according to some embodiments; and

FIG. 5 is a graph of DT across a TEG vs distance across a TEG for modelled thermoelectric apparatus without a heat transfer element.

### DETAILED DESCRIPTION

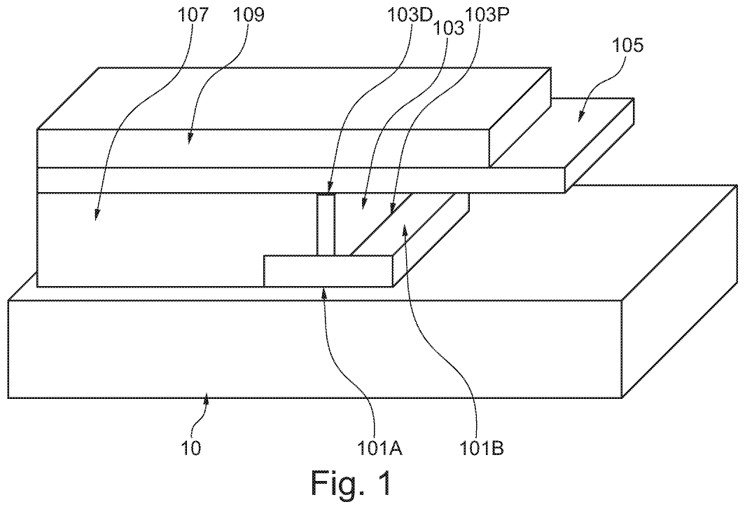

FIG. 1 illustrates thermoelectric apparatus according to some embodiments applied to a heated surface of an object 10.

The object 10 having a heated surface may be, without limitation: a heated pipe; a boiler; or electrical equipment.

In use, the heated surface may have at a temperature of at least 30° C., optionally at least 40° C., optionally at least 50° C. The heated surface may have a temperature of up to 100° C., optionally up to 200° C.

According to some embodiments, the thermoelectric apparatus comprises a TEG 101, a thermally conductive heat transfer element 103 and a thermally conductive heat spreader 105.

In use, a first surface 101A of the TEG (the “hot” side of the TEG when in use), which may be a surface of a substrate of the TEG, may be in thermal contact with a heated surface of an object 10. A proximal end 103P of the thermally conductive heat transfer element 103 is in thermal contact with an opposing second surface 101B of the thermoelectric generator (the “cold” side of the TEG when in use). A distal end 103D of the thermally conductive heat transfer element is in thermal contact with a thermally conductive heat spreader 105.

By “thermal contact” between two surfaces as used herein is meant that the two surfaces are in direct contact or a thermally conductive material, e.g. a thermally conductive adhesive, is disposed between the two surfaces.

The proximal end 103P of the thermally conductive heat transfer element 103 may be in direct contact with second surface 101B of the thermoelectric generator.

The proximal end 103P of the thermally conductive heat transfer element 103 may be affixed to the second surface 101B of the thermoelectric generator by any suitable fixing means, for example a thermally conductive adhesive, e.g. thermally conductive epoxy, or solder. A thermally conductive adhesive as described herein optionally has a thermal conductivity of at least 1 W/mK.

The distal end 103D of the thermally conductive heat transfer element 103 may be in direct contact with a thermally conductive surface of the thermally conductive heat spreader.

The distal end 103D of the thermally conductive heat transfer element 103 may be affixed to a thermally conductive surface of the thermally conductive heat spreader by any suitable fixing means, for example a thermally conductive adhesive, e.g. thermally conductive epoxy, or solder.

The thermally conductive heat spreader 105 has a larger surface area than the surface area of distal end 103D. Optionally, the thermally conductive heat spreader has a surface area greater than the surface area of the TEG.

The TEG is spaced apart from the thermally conductive heat spreader. In some embodiments, the distance between the TEG and the heat spreader is at least 0.5 cm, optionally at least 1 cm, optionally up to 10 cm or up to 20 cm.

Thermal insulation 107 may be disposed between the TEG 101 and the heat spreader 105. Thermal insulation 107 may cover some or all of the second surface of the TEG which is not covered by the thermally conductive heat transfer element 103. Thermal insulation 107 may have one surface contacting the TEG and an opposing surface contacting the thermally conductive heat spreader.

The thermally conductive heat spreader may cover some or all of the area of an outer surface of the thermal insulation 107. Optionally, the thermally conductive heat spreader is wrapped around an outer surface of the thermal insulation, e.g. thermal insulation around a heated pipe.

In operation, heat may be drawn from the second surface 101B of the thermoelectric generator by the thermally conductive heat transfer element 103 towards the thermally conductive heat spreader 105 which may dissipate heat received from the thermally conductive heat transfer element 103 across some or all of the surface area of the thermally conductive heat spreader 105.

In some embodiments, a further thermal insulator 109 comprising one or more thermally insulating layers is disposed over the thermally conductive heat spreader 105. Further thermal insulator 109 may cover some or all of an outer surface area of the thermally conductive heat spreader 105.

By providing the further thermal insulator 109, heat may be drawn away from the second surface of the TEG whilst limiting dissipation of that heat into the surrounding environment. In some embodiments, the thermally conductive heat spreader 105 may be laminated to a layer of the further thermal insulator 109.

Thermal insulation as described herein may comprise or consist of any known thermal insulators including, without limitation, fiberglass, mineral wool, cellulose, polyurethane and polystyrene and combinations thereof.

The components of the thermoelectric apparatus may be provided in kit form. The kit may contain the TEG, the thermally conductive heat transfer element and the thermally conductive heat spreader. The kit may contain a thermally conductive adhesive. The kit may contain insulation for application over the thermally conductive heat spreader. The kit may contain instructions for assembly of the apparatus. The instructions may be in written form, e.g. printed on paper or provided on a machine readable medium. The kit may be provided in packaging.

The thermoelectric apparatus may be applied to an object having a heated surface which is or is not insulated.

If the heated surface is insulated then insulation may be removed to expose the surface and re-applied over the thermoelectric device with the thermally conductive heat spreader extending through the insulation to contact the thermally conductive heat spreader. Further insulation may be applied over the thermally conductive heat spreader.

In some embodiments, the TEG and/or the thermally conductive heat spreader may be incorporated into a thermal insulator.

In some embodiments, a thermal insulator may comprise one or more thermally conductive heat spreaders incorporated therein. It will be understood that a thermally conductive heat spreader incorporated into a thermal insulator will extend through the thickness of the thermal insulator.

In some embodiments, a thermal insulator may comprise one or more TEGs incorporated therein or laminated thereto. It will be understood that the first surface of a TEG incorporated into, or laminated to, a thermal insulator will be exposed.

In some embodiments, the thermally conductive heat spreader may be laminated to a surface of a thermal insulator.

A length of the thermal insulator, comprising one or more of the TEG, the thermally conductive heat transfer element and the thermally conductive heat spreader incorporated therein or laminated thereto, may be stored in a rolled form.

The thermally conductive heat transfer element and the thermally conductive heat spreader each comprise or consist of one or more thermally conductive materials.

In some embodiments the thermally conductive heat transfer element and/or the thermally conductive heat spreader comprises or consists of a material or a mixture of materials having a thermal conductivity of at least 30 W/mK.

In some embodiments, thermally conductive materials of the thermally conductive heat transfer element and/or the heat spreader are selected from metals; metal alloys; and graphite. Preferably, metals of a metallic or metal alloy heat transfer element or heat spreader are selected from aluminium and transition metals, e.g. aluminium, iron, copper or steel.

In some embodiments, the thermally conductive heat transfer element comprises a single cooling fin extending between the TEG and the heat spreader.

In some embodiments, the heat transfer element comprises a plurality of laterally spaced cooling fins extending between the TEG and the heat spreader. The plurality of laterally spaced cooling fins may extend from a thermally conductive base wherein the base comprises the proximal end of the thermally conductive heat transfer element.

The or each fin of the heat transfer element may have any shape. In some embodiments, the or each fin is rectangular.

The proximal end of the heat transfer element extends across at least part of the length or width of the TEG. In some embodiments, the proximal end of the heat transfer element extends across substantially the full length and/or the full width of the TEG.

In some embodiments, the heat transfer element is disposed over a central area of the TEG, with areas of the TEG on either side of the central area being uncovered by the heat transfer element.

In some embodiments, the heat transfer element is disposed over some or all of a notional centre line bisecting the TEG.

Optionally, the TEG has a surface area in the range of 5-200 cm².

Optionally, the heat transfer element has a height of 0.5 cm, optionally at least 1 cm, optionally up to 10 cm or up to 20 cm. By “height” of the heat transfer element as used herein is meant the distance that the heat transfer element extends above the second surface of the TEG.

Optionally, the heat transfer element has a thickness in the range of about 0.5-2 cm.

Optionally, the distal end and/or proximal end of the thermally conductive heat transfer element may be curved, e.g. to conform to a TEG or a thermally conductive heat spreader, respectively, which is curved when in use.

Optionally, the heat spreader is a flexible thermally conductive foil, optionally a flexible metal foil, for example an aluminium or copper foil. In some embodiments, the flexible thermally conductive foil may be laminated to one or more additional layers, optionally one or more polymer layers.

Optionally, the thermally conductive heat spreader has a thickness of at least 0.1 mm.

FIG. 1 illustrates apparatus having a single heat transfer element between the TEG and the heat spreader. In other embodiments, a plurality of heat transfer elements may be disposed between the TEG and the heat spreader.

For simplicity, FIG. 1 illustrates a single TEG, although it will be understood that a plurality of TEGs may be provided spaced apart on the surface of the heated object, for example a plurality of TEGs positioned at regular or irregular intervals on a heated pipe, each TEG being associated with one or more thermally conductive heat transfer elements for transfer of heat from the TEG to the thermally conductive heat spreader.

In some embodiments, the plurality of TEGs may be in thermal communication with a single heat spreader extending across the plurality of TEGs.

In some embodiments, the apparatus may comprise a plurality of TEGs and a plurality of heat spreaders, each heat spreader being associated with at least one of the plurality of TEGs.

The TEG may be flexible. The TEG may have a bend radius of 30 mm or less, optionally 20 mm or less. In some embodiments, the bend radius may be at least 5 mm or at least 10 mm.

Optionally, in use the first surface of the TEG conforms to a non-planar heated surface of the object on which it is located, optionally a curved surface.

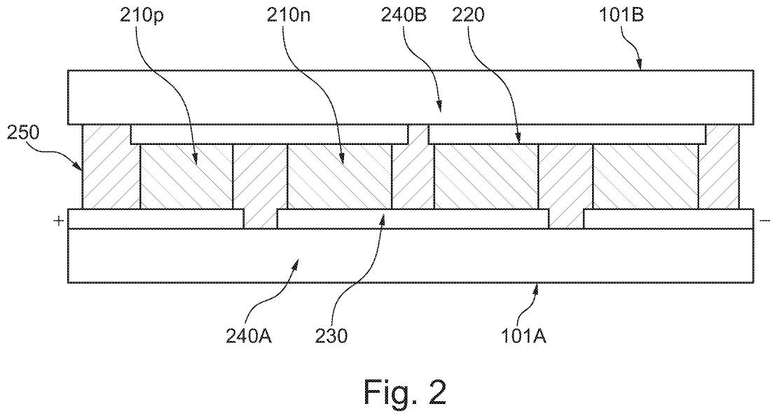

FIG. 2 illustrates a TEG according to some embodiments. The TEG comprises one or more thermoelectric couples, each thermoelectric couple comprising a p-type thermoelectric leg 210p electrically coupled by a contact 220 to an n-type thermoelectric leg 210n. If the TEG comprises a plurality of thermoelectric couples then adjacent couples may be electrically connected by an electrical contact 230. For simplicity, FIG. 2 illustrates only two thermoelectric couples however it will be understood that the TEG may comprise a larger number of electrically connected thermoelectric couples, e.g. thermoelectric couples connected in series.

The TEG may comprise a first substrate 240A having the first surface 101A and a second substrate 240B having the second surface 101B, the one or more thermoelectric couples of the TEG being disposed between the first and second substrate.

Optionally, volume between the first and second substrates which is not occupied by the one or more thermoelectric couples and contacts therebetween may be occupied by an electrical insulator 250.

Each of the first and second substrate may consist of a single layer or may comprise a plurality of layers. In some embodiments at least one, optionally both, of the first and second substrate comprises or consists of an electrically insulating layer, e.g. a polymer layer, and a metal foil layer, e.g. an aluminium or copper layer.

The p-type semiconductor and the n-type semiconductor of, respectively, the p-type thermoelectric legs and the n-type thermoelectric legs may be selected from known thermoelectric materials as disclosed in, for example, J. Mater. Chem. C, 2015, 3, 10362 and Chem. Soc. Rev., 2016, 45, 6147-6164, the contents of which are incorporated herein by reference.

In some embodiments, each n-type thermoelectric leg may comprise an alloy of bismuth, and tellurium or selenium. In some embodiments, the semiconducting material of each n-type thermoelectric leg may comprise or consist of an alloy of bismuth (Bi), and tellurium (Te) or selenium (Se), for example, Bi₂Te₃, and Bi₂Se₃, and/or optionally an n-type dopant. Examples of n-type dopants include selenium (Se), bismuth (Bi), sulfur (S), iodine (I) and/or the like. In some embodiments, the concentration of the n-type dopant may be between 1 and 10 weight %.

In some embodiments, the p-type thermoelectric element may comprise an alloy of bismuth, tellurium and antimony. In some embodiments, the semiconducting material of each p-type thermoelectric leg may comprise or consist of an alloy of bismuth (Bi), tellurium (Te), and antimony (Sb), for example Bi_{1.5}Sb_{0.5}Te₃, and optionally a p-type dopant. In some embodiments, the second semiconducting particles may comprise or consist of an alloy of lead (Pb) and tellurium (Te), an alloy of tin (Sn) and selenium (Se), or an alloy of silicon (Si) and germanium (Ge), and optionally a p-type dopant. Examples of p-type dopants include tellurium (Te), selenium (Se), sulfur (S), arsenic (As), antimony (Sb), phosphorus (P), bismuth (Bi) and the halogens. The concentration of the p-type dopant may be between 1 and 10 weight %.

Each electrical contact described herein comprises one or more conductive layers. Examples of conductive materials for the conductive layer or layers of the electrical contacts include metals, such as copper or gold; metal alloys; conductive metal oxides; and conductive polymers. Optionally, each contact described herein has a thickness between 1 and 5 μm. Each electrical contact described herein may be formed by any suitable technique known to the skilled person, for example sputtering, thermal evaporation or printing, e.g. printing of a metallic paste.

In some embodiments, the TEG may form part of a sensor system, optionally a humidity or temperature sensor system, in which a sensor is powered by the TEG.

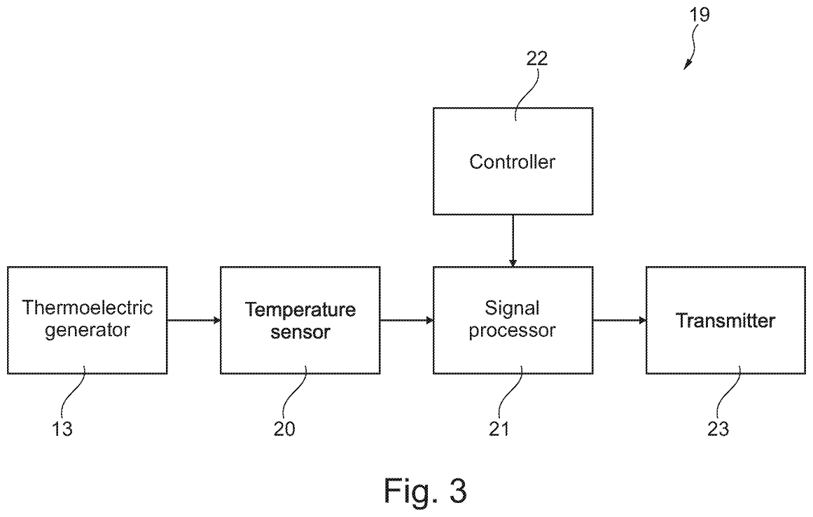

With reference to FIG. 3, a temperature sensor system according to some embodiments may comprise the TEG 13, a temperature sensor 20, a signal processor unit 21, a controller unit 22, and a transmitter unit 23.

The signal processor 21 receives at least one signal from the temperature sensor 20. The signal indicates the temperature of the component.

In response to receiving control signals from the controller 22, the signal processor 21 processes the signal. The transmitter 23 receives the processed signal and transmits the processed signal to the external receiver (not shown).

In some embodiments, a temperature sensor system may be configured to determine a temperature from the output of the TEG in which case a separate temperature sensor may or may not be present. According to these embodiments, the temperature sensor system may be as described with reference to FIG. 3 except that the TEG may be connected directly to the signal processor unit 21 and the signal processor unit may be configured to determine a temperature from the output of the TEG.

### EXAMPLES

Finite element modelling of apparatus illustrated in FIG. 1 was carried out using heat transfer modelling software available from COMSOL Ltd. in which:

the TEG has dimensions of 50×50×0.35 mm, has a thermal conductivity of 0.18 W/mK and has a 0.2 mm thick copper sheet disposed on its second surface (i.e. the surface in contact with the heat transfer element);

the heat transfer element is a rectangle of 20 mm height×50 mm width×10 mm thickness of copper metal positioned upright along a notional centre line of the TEG;

the heat spreader is a 0.2 mm thick, 41 cm long copper foil spaced apart from the TEG by the 20 mm height of the heat transfer element and the 20 mm thick thermal insulation disposed between the heat spreader and the TEG; and

the further (top) thermal insulation layer has a thickness of 13 mm.

The temperatures of the hot and cold sides of the TEG were 120° C. and 20° C. respectively.

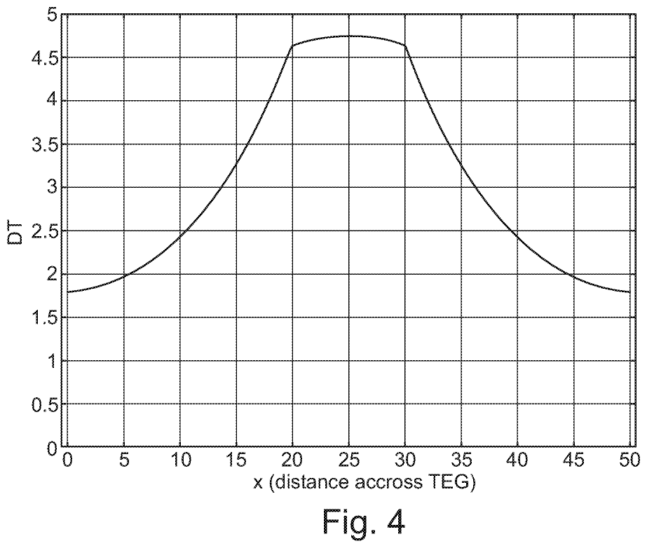

With reference to FIG. 4, DT of the TEG rises sharply at the centre of the TEG where the heat transfer element is placed (DT=4.75K) and is significantly lower at the edges of the TEG remote from the heat transfer element (DT=1.8K).

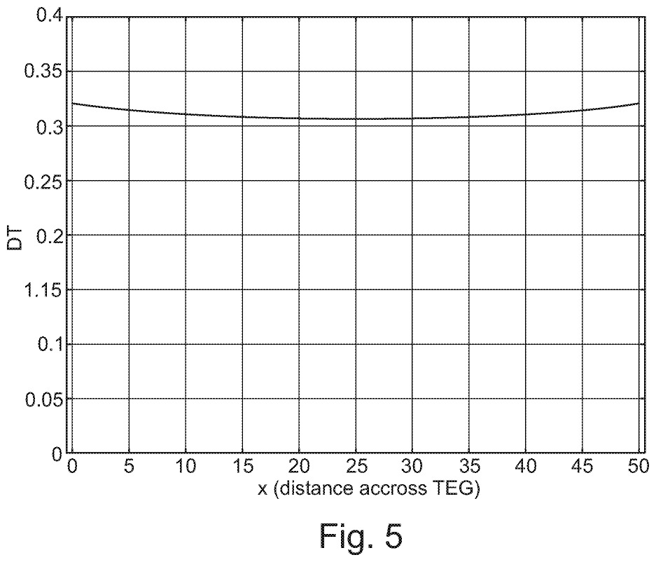

For comparison, apparatus as described above was modelled but without the heat transfer element. With reference to FIG. 5, there is little variation in DT across the TEG.

The description above provides preferred exemplary embodiment(s) only, and is not intended to limit the scope, applicability or configuration of the invention. Rather, the ensuing description of the preferred exemplary embodiment(s) will provide those skilled in the art with an enabling description for implementing a preferred exemplary embodiment of the invention, it being understood that various changes may be made in the function and arrangement of elements, including combinations of features from different embodiments, without departing from the scope of the invention.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while some aspect of the technology may be recited as a computer-readable medium claim, other aspects may likewise be embodied as a computer-readable medium claim, or in other forms, such as being embodied in a means-plus-function claim.

In the description above, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

1. Thermoelectric apparatus comprising:
a thermoelectric generator having first surface configured to contact a heated surface and an opposing second surface;
a thermally conductive heat spreader; and
a thermally conductive heat transfer element having a proximal end in thermal contact with the second surface of the thermoelectric generator and a distal end in thermal contact with the thermally conductive heat spreader,
wherein the thermally conductive heat spreader is spaced apart from the thermoelectric generator and wherein the thermally conductive heat spreader has a surface area larger than a surface area of the distal end of the thermally conductive heat transfer element, and wherein the distance between the thermoelectric generator and the heat spreader is at least 0.5 cm.

2. The thermoelectric apparatus according to claim 1 wherein the thermally conductive heat spreader has a surface area larger than a surface area of the thermoelectric generator.

3. The thermoelectric apparatus according to claim 1 wherein the thermally conductive heat transfer element comprises a single thermally conductive fin extending between the thermoelectric generator and the thermally conductive heat spreader.

4. The thermoelectric apparatus according to claim 1 wherein the thermally conductive heat spreader comprises a metal.

5. The thermoelectric apparatus according to claim 4 wherein the thermally conductive heat spreader comprises a flexible metal foil.

6. The thermoelectric apparatus according to claim 1 wherein a first thermal insulator is disposed between the thermoelectric generator and the thermally conductive heat spreader.

7. The thermoelectric apparatus according to claim 6 wherein the thermally conductive heat spreader is incorporated into the first thermal insulator.

8. The thermoelectric apparatus according to claim 6 wherein the TEG is laminated to or incorporated into the first thermal insulator.

9. The thermoelectric apparatus according to claim 6 wherein the thermally conductive heat spreader is laminated to a surface of the first thermal insulator.

10. The thermoelectric apparatus according to claim 1 wherein a second thermal insulator is disposed over the thermally conductive heat spreader.

11. The thermoelectric apparatus according to claim 1 wherein a second thermal insulator is disposed over, and laminated to, the thermally conductive heat spreader.

12. A sensor system comprising the thermoelectric apparatus according claim 1 and a sensor powered by the thermoelectric generator.

13. The sensor system according to claim 12 wherein the sensor is a temperature sensor.

14. A method of forming the thermoelectric apparatus according to claim 1 comprising: applying the thermoelectric generator to a surface of an object wherein the temperature of the surface increases when the object is in use; disposing the thermally conductive heat transfer element over the second surface of the thermoelectric generator; and disposing the thermally conductive heat spreader over the thermally conductive heat transfer element and spaced apart from the thermoelectric generator.

15. The method according to claim 14 wherein a thermal insulator is disposed between the thermoelectric generator and the thermally conductive heat spreader.

16. A kit for assembly of a thermoelectric apparatus comprising:
a thermoelectric generator having first surface configured to contact a heated surface and an opposing second surface;
a thermally conductive heat transfer element having a proximal end configured to contact the second surface of the thermoelectric generator and to draw heat from the second surface of the thermoelectric generator to the distal end; and
a thermally conductive heat spreader configured to contact the distal end of the thermally conductive heat transfer element, the thermally conductive heat spreader having a surface area larger than a surface area of the distal end of the thermally conductive heat transfer element, wherein the kit is configured such that a distance between the thermoelectric generator and the heat spreader upon assembly of the kit is at least 0.5 cm.

17. The kit according to claim 16 further comprising a thermally conductive adhesive for adhering the proximal end of the thermally conductive heat transfer element to the second surface of the thermoelectric generator and/or for adhering the distal end of the thermally conductive heat transfer element to the thermally conductive heat spreader.

18. The kit according to claim 16 wherein the kit further comprises a first thermal insulator and wherein:
the thermally conductive heat spreader is incorporated into a first thermal insulator; and/or the TEG is laminated to or incorporated into a first thermal insulator; and/or the thermally conductive heat spreader is laminated to the first thermal insulator.

19. The kit according to claim 16 further comprising a second thermal insulator having at least the same surface area as the thermally conductive heat spreader.

20. The kit according to claim 19 wherein the thermally conductive heat spreader is laminated to a surface of the second thermal insulator.

21. (canceled)
